(19) United States
(12) Patent Application Publication
(10) Pub. No.: US 2026/0324011 A1
(43) Pub. Date: Oct. 15, 2026

(54) SCHOTTKY BARRIER DIODE STRUCTURE

(71) Applicant: Microchip Technology Incorporated, Chandler, AZ (US)

(72) Inventors: Shesh Mani Pandey, Gilbert, AZ (US); Bruce Odekirk, Portland, OR (US)

(73) Assignee: Microchip Technology Incorporated, Chandler, AZ (US)

(21) Appl. No.: 19/466,389

(22) Filed: Jan. 31, 2026

Related U.S. Application Data
(60) Provisional application No. 63/756,662, filed on Feb. 10, 2025.

(51) Int. Cl. H10D 62/10; H10D 8/60

(52) U.S. Cl. CPC H10D 62/106; H10D 8/60

(57) ABSTRACT

A Schottky barrier diode (SBD) comprises a volume of semiconductor material presenting opposite first and second ends, a metal layer contacting the first end to define a Schottky contact, and a plurality of doped material pockets dispersed in the volume of semiconductor material adjacent the first end. Each of the doped material pockets extend from the first end to define a cross-sectional shape relative to the direction of extension. The cross-sectional shape of each of the doped material pockets presents a body and a projection extending laterally from the body.

### CROSS-REFERENCE TO RELATED APPLICATIONS

The current patent application claims the benefit under 35 U.S.C. §119(e) of the priority date of U.S. Provisional Application Ser. No. 63/756,662 titled “SCHOTTKY BARRIER DIODE STRUCTURE” and filed Feb. 10, 2025. The Provisional Application is hereby incorporated by reference, in its entirety, into the current patent application as if fully set forth herein.

### TECHNICAL FIELD

The present disclosure relates to Schottky barrier diodes.

### BACKGROUND

A Schottky barrier diode (SBD) is a semiconductor diode formed by the junction of a semiconductor with a metal. The relatively low forward voltage of SBDs is desirable for applications requiring fast switching, such as power systems, radio frequency (RF) systems, and logic circuits. It is generally desirable to improve the performance and reduce the cost of SBDs, but it can be difficult to do so.

This background discussion is intended to provide related information, and is not necessarily prior art.

### SUMMARY OF THE INVENTION

In various examples of the present disclosure, a Schottky barrier diode (SBD) comprises a volume of semiconductor material presenting opposite first and second ends, a metal layer contacting the first end to define a Schottky contact, and a plurality of doped material pockets dispersed in the volume of semiconductor material adjacent the first end. Each of the doped material pockets extend from the first end to define a cross-sectional shape relative to the direction of extension. The cross-sectional shape of each of the doped material pockets presents a body and a projection extending laterally from the body.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 is a cross-sectional elevation view of an example SBD in accordance with various examples of the present disclosure;

FIG. 2 illustrates a plan view of an example SBD, with the metal layer removed to depict complementary doped material extensions in accordance with various examples of the present disclosure;

FIG. 3 illustrates a plan view of another example SBD similar to FIG. 2, but depicting alternative doped material extensions in accordance with various examples of the present disclosure; and

FIG. 4 illustrates an example method for making an SBD in accordance with various examples of the present disclosure.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a Schottky barrier diode (SBD). The example SBD may be suitable for high-voltage applications and may operate at a voltage greater than one thousand (1,000) volts (V). More specifically, the example SBD may be rated for a voltage of around twelve hundred (1,200) V. It will be appreciated by one of ordinary skill in the art that the example SBD may be suitable for lower voltage applications without departing from the scope of the present disclosure. The example SBD may be implemented as a stand-alone device, or may be integrated with other devices (e.g., other diodes, transistors, and the like) as part of a semiconductor package.

An example SBD includes a volume of semiconductor material, a metal layer, and a plurality of doped material pockets. The volume of semiconductor material presents opposite first and second ends. The plurality of doped material pockets are located adjacent the first end. The metal layer contacts the first end to define a Schottky contact. The doped material pockets are dispersed in the volume of semiconductor material adjacent the first end, such that the Schottky contact is located between the doped material pockets. Each of the doped material pockets extend from the first end to define a cross-sectional shape relative to the direction of the extension. The cross-sectional shape of each of the doped material pockets includes a body and a projection extending laterally from the body, wherein the projection and body cooperatively define a recess. Adjacent doped material pockets present opposed ones of the projections and recesses to thereby minimize a gap between adjacent ones of the doped material pockets. The doped material pockets may reduce the electric field (e.g., by increasing the resistance) at the first end to reduce leakage current and improve reverse bias characteristics of the example SBD.

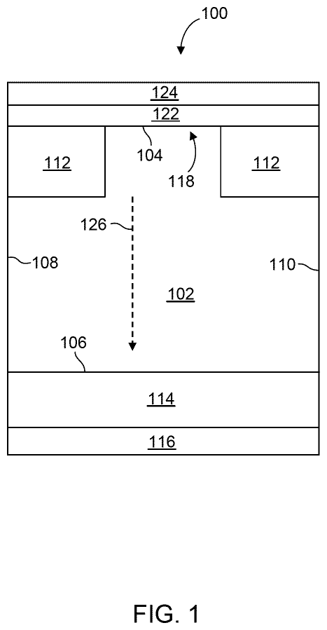

Referring to FIG. 1, an example of an SBD 100 is shown. The SBD 100 may generally include a volume of semiconductor material 102, pockets of doped material 112, and a metal layer 118.

The volume of semiconductor material 102 may present a first end 104, a second end 106 opposite and vertically spaced from the first end 104, a first side 108, and a second side 110 opposite and laterally spaced from the first side 108. The volume of semiconductor material 102 may be constructed from or include an N-type epitaxial semiconductor material, such as silicon carbide (SiC). However, it is within the ambit of certain aspects of the present disclosure that the volume of semiconductor material 102 may be constructed from silicon.

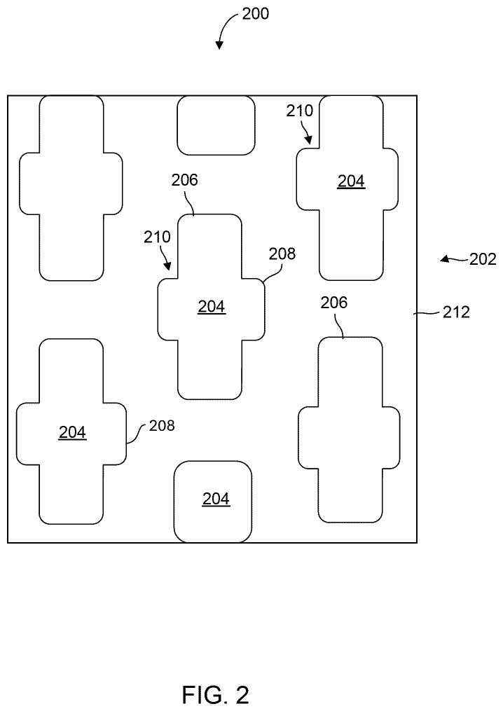

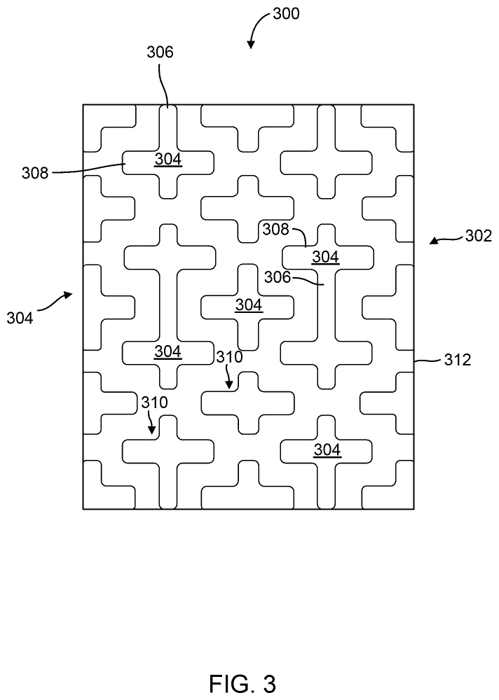

The pockets of doped material 112 may be constructed from or otherwise include a P+ material. The pockets of doped material 112 may be laterally spaced between the first side 108 and the second side 110. The pockets of doped material 112 may be implanted, deposited, or otherwise provided adjacent the first end 104. The pockets of doped material 112 may extend from the first end 104 toward the second end 106. The pockets of doped material 112 may be identical in shape and uniformly arranged in a repeating pattern, although certain SBD examples contemplate variously shaped pockets, unequal spacing between the pockets, etc. Additional details of the shape and configuration of the pockets of doped material 112 are described in connection with FIGS. 2 and 3.

In various examples, the volume of semiconductor material 102 may include an N+ doped region adjacent the first end 104. The N+ doped region may extend between each of the pockets of doped material 112.

A cathode substrate 114 is located at the second end 106 of the volume of semiconductor material 102 and may be constructed from or include an N+ substrate material. The volume of semiconductor material 102 may be grown or otherwise formed on the cathode substrate 114. A cathode contact 116 may be located adjacent the cathode substrate 114 and spaced apart from the second end 106.

The metal layer 118 may form a Schottky contact with the volume of semiconductor material 102. The metal layer 118 may include a Schottky barrier metal 122 contacting the first end 104 of the volume of semiconductor material 102. The Schottky metal 122 may include titanium, molybdenum, platinum, chromium, tungsten, aluminum, nickel, and the like, and combinations thereof.

An anode contact 124 may be located adjacent the Schottky metal 122. The anode contact 124 may be spaced apart from the first end 104. The Schottky metal 122 may contact the anode contact 124, such that the Schottky metal 122 extends continuously between the first end 104 of the volume of semiconductor material 102 and the anode contact 123. The anode contact 124 may include a conductive metal, such as aluminum, copper, nickel, or combinations thereof. In various examples, the anode contact 124 and the Schottky metal 122 may be formed of dissimilar metals, although alternative examples contemplate forming the anode contact and the metal layer of the same material.

According to various examples, a diffusion barrier metal (not shown) may be provided between the Schottky metal 122 and the anode contact 124. The diffusion barrier metal may be formed of titanium tungsten, titanium nitride, or combinations thereof.

A channel 126 may be provided by a channel portion of the volume of semiconductor material 102. The channel 126 may extend through the volume of semiconductor material 102 between the first end 104 and the cathode substrate 114. The majority charge carriers may move and the electrical current may flow through the channel 126. It will be understood by one of ordinary skill in the art that the dashed line representing the channel 126 is merely representative and charge carriers moving through the channel 126 do not necessarily follow a single, straight line.

Referring to FIG. 2, an example SBD 200 is shown. The SBD 200 includes a volume of semiconductor material 202 and pockets of doped material 204. The volume of semiconductor material may present a first end 212. The example SBD 200 may be representative of a top view of the SBD 100 of FIG. 1, with the Schottky metal layer and the anode contact removed to show the pockets of doped material.

The SBD 200 may include the metal layer (not shown), an anode contact (not shown), a cathode substrate (not shown), and a cathode contact (not shown). These elements are described in detail in connection with FIG. 1 and are not described again here for brevity.

Respective ones of the doped material pockets 204 may extend from the first end 212 (e.g., as shown in FIG. 1) to define a cross-sectional shape (e.g., as shown in FIG. 2) relative to the direction of extension. The cross-sectional shape of the doped material pockets 204 may present a body 206 and a projection 208 extending laterally from the body 206.

The body 206 and the projection 208 of the doped material pockets 204 may cooperatively form a recess 210. Adjacent doped material pockets 204 may present an opposed projection 208 and recess 210 pair to thereby minimize a gap between the adjacent doped material pockets 204. Minimizing the gap between the adjacent doped material pockets 204 may reduce the electric field (e.g., by increasing the resistance) at the first end 212 to reduce leakage current and improve reverse bias characteristics of the example SBD 200.

In various examples, the opposed body 206 and projection 208 of adjacent doped material pockets 204 may present complementary shapes. The pockets 204 may be arranged in a uniform pattern to minimize gaps between adjacent doped material pockets 204. The body 206 and the projections 208 of each pocket 204 may generally present orthogonal shapes, and the projections 208 may extend transversely from a central portion of the body 206. The recesses may define interior corners cooperatively presented by the body 206 and the projections 208. The interior corners may define an interior right angle, although certain aspects contemplate the interior corners as being rounded or having an alternative shape. Furthermore, according to some aspects, the interior corners may be variously shaped, such that one or more corners are different from the others.

In various examples, the cross-sectional shape of each of the doped material pockets 204 may be a cruciform. The doped material pockets 204 may be uniformly arranged in a repeating pattern. However, certain SBD examples contemplate variously shaped pockets, unequal spacing between the pockets, equally spaced pockets having a shape other than a cruciform, etc.

The metal layer and the first end 212 may cooperatively form a Schottky contact 214. The Schottky contact 214 may be located between the doped material pockets 204. The repeating pattern of the doped material pockets 204 may be configured so that Schottky contact 214 is uninterrupted. Accordingly, the Schottky contact 214 may be continuous across the first end 212 except for where the doped material pockets 204 are located.

Referring to FIG. 3, an example SBD 300 is shown. The SBD 300 includes a volume of semiconductor material 302 and pockets of doped material 304. The volume of semiconductor material may present a first end 312. The example SBD 300 may be representative of a top view of the SBD 100 of FIG. 1, with the Schottky metal and the anode contact removed to show the pockets of doped material.

The SBD 300 may include the Schottky metal (not shown), the anode contact (not shown), a cathode substrate (not shown), and a cathode contact (not shown). These elements are described in detail in connection with FIG. 1 and are not described again here for brevity.

Respective ones of the doped material pockets 304 may extend from the first end 312 (e.g., as shown in FIG. 1) to define a cross-sectional shape (e.g., as shown in FIG. 3) relative to the direction of extension. The cross-sectional shape of the doped material pockets 304 may present a body 306 and a projection 308 extending laterally from the body 306.

The body 306 and the projection 308 of the doped material pockets 304 may cooperatively form a recess 310. Adjacent doped material pockets 304 may present an opposed projection 308 and recess 310 pair to thereby minimize a gap between the adjacent doped material pockets 304. Minimizing the gap between the adjacent doped material pockets 304 may reduce the electric field (e.g., by increasing the resistance) at the first end 312 to reduce leakage current and improve reverse bias characteristics of the example SBD 300.

In various examples, the projection 308 of the pair may extend into the recess 310 of the pair. For example, respective ones of the projections 308 (e.g., the projections 308 shown in the middle column and on the outermost columns shown in FIG. 3) may extend into the recesses 310 of adjacent doped material pockets 304 (e.g., the doped material pockets 304 shown on either side of the middle column of FIG. 3).

Respective ones of the bodies 306 may include opposite sides. At least some of the doped material pockets 304 (e.g., some of the doped material pockets 304 shown on either side of the middle column of FIG. 3) may include a pair of projections extending from one of the sides. The recess 310 may be defined between the pair of projections 308. Similarly, at least some of the doped material pockets 304 may include a pair of projections extending from both of the sides, with the recesses 310 being defined between the pair of projections 308.

In various examples, the opposed body 306 and projection 308 of adjacent doped material pockets 304 may present complementary shapes. The pockets 304 may be arranged in a uniform pattern to minimize gaps between adjacent doped material pockets 304. The body 306 and the projections 308 of each pocket 304 may generally present orthogonal shapes. The recesses 310 may define interior corners cooperatively presented by the body 306 and the projections 308. The interior corners may define an interior right angle, although certain aspects contemplate the interior corners as being rounded or having an alternative shape. Furthermore, according to some aspects, the interior corners may be variously shaped, such that one or more corners are different from the others.

The metal layer and the first end 312 may cooperatively form a Schottky contact 314. The Schottky contact 314 may be located between the doped material pockets 304. The repeating pattern of the doped material pockets 304 may be configured so that Schottky contact 314 is uninterrupted. Accordingly, the Schottky contact 314 may be continuous across the first end 312 except for where the doped material pockets 304 are located.

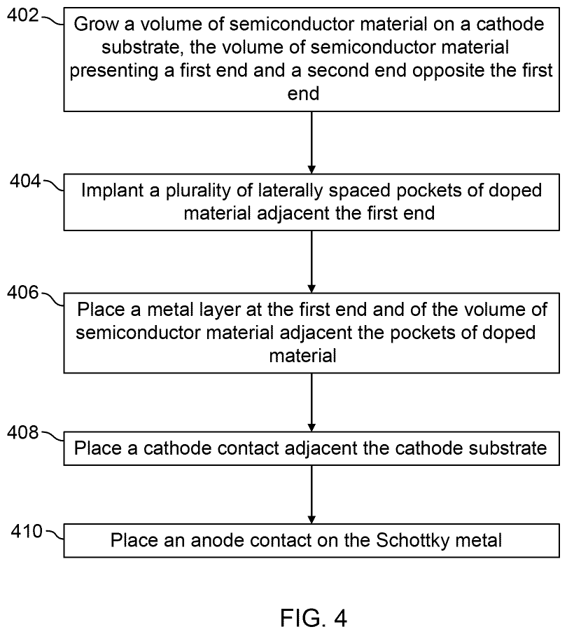

Referring to FIG. 4, an example method 400 of manufacturing an SBD, such as the SBD 100 described above, may include the operations set forth below.

At operation 402, the method 400 begins by epitaxially growing a volume of semiconductor material, including a first end, a second end, a first side and a second side, on a substrate material. The substrate material may be a cathode substrate constructed from or otherwise including an N+ substrate material. The semiconductor material may be an N-type semiconductor material. In various examples, the semiconductor material may include silicon carbide (SiC).

At operation 406, a plurality of pockets of doped material may be implanted (e.g., via ion implantation), deposited, or otherwise provided adjacent the first end. The doped material pockets may extend from the first end toward the second end. The doped material pockets 308 may be constructed from or otherwise include a P+ material. According to certain examples, the doped material pockets may alternatively be formed of a single unitary implant which may or may not be subsequently modified (e.g., by etching or other suitable techniques).

The pockets of doped material may be shaped in a repeating pattern (e.g., as shown in FIGS. 2 and 3). Each pocket of doped material may extend from the first end to define a cross-sectional shape relative to the direction of extension. The cross-sectional shape of each of the doped material pockets may present a body and at least one projection extending laterally from the body, as shown in FIGS. 2 and 3.

Implanting the doped material pockets may include placing a mask across the first end of the volume of semiconductor material. The mask may present gaps having a pattern (e.g., one of the patterns shown in FIGS. 2 and 3). The doped material pockets may be implanted into the first end through the gaps. According to certain examples, the doped material pockets may alternatively be formed of a single unitary implant which may or may not be subsequently modified (e.g., by etching or other suitable techniques).

Referring to operation 406, a metal layer may be placed at the first end adjacent the pockets of doped material. The metal layer may be referred to as a Schottky metal. The Schottky metal may include titanium, molybdenum, platinum, chromium, tungsten, aluminum, nickel, and combinations thereof. The Schottky metal may contact the doped material pockets and the first end of the drift region. The contact of the Schottky metal and the drift region may form a Schottky contact. The repeating pattern of the doped material pockets may be configured so that the Schottky contact is uninterrupted. Accordingly, the Schottky contact may be continuous across the first end of the volume of semiconductor material except for where the doped material pockets are located.

Referring to operation 408, a cathode contact is placed adjacent the cathode substrate. The cathode contact may be formed of a conductive metal, such as aluminum, nickel, copper, and combinations thereof. The cathode contact may contact the cathode substrate and may be spaced apart from the second end. The cathode contact may span the cathode substrate.

Referring to operation 410, an anode contact is placed on the Schottky metal. The anode contact may contact the Schottky metal. Specifically, the anode contact may contact a diffusion metal layer of the Schottky metal, such that the diffusion metal layer is interposed between the anode contact and the Schottky barrier metal. As noted above, the Schottky metal and the anode contact may be formed of dissimilar metals.

### FEATURE COMBINATIONS

In accordance with various examples of the present disclosure, a Schottky barrier diode (SBD) may comprise a volume of semiconductor material presenting opposite first and second ends, a metal layer contacting the first end to define a Schottky contact, and a plurality of doped material pockets dispersed in the volume of semiconductor material adjacent the first end. Each of the doped material pockets may extend from the first end to define a cross-sectional shape relative to the direction of extension. The cross-sectional shape of each of the doped material pockets may present a body and a projection extending laterally from the body.

The preceding examples may include any one or more of the following features.

The doped material pockets may be uniformly arranged in a repeating pattern.

The Schottky contact may be located between the doped material pockets.

The metal layer may include a metal being selected from the group consisting of: titanium, molybdenum, platinum, chromium, tungsten, aluminum, and combinations thereof.

The repeating pattern may be configured so that the Schottky contact is uninterrupted.

The projection and body may cooperatively define a recess, with adjacent doped material pockets presenting an opposed projection and recess pair to thereby minimize a gap between the adjacent ones of the doped material pockets.

The projection of the pair may extend into the recess of the pair.

The body may include opposite sides. At least some of the doped material pockets may include a pair of the projections extending from one of the sides, with the recess being defined between the pair of projections.

The projection and recess of the pair may present complementary shapes.

Each of the projections may be orthogonal, and each of the recesses may define an interior right angle.

The cross-sectional shape of each of the doped material pockets may be a cruciform.

The repeating pattern being configured so that the Schottky contact is uninterrupted.

The SBD may comprise a cathode substrate located at the second end.

The cathode substrate may include an N+ material.

The volume of semiconductor material may include an N-type epitaxial material.

The doped material pockets may include a P+ material.

The SBD may comprise a cathode contact located adjacent the cathode substrate.

The SBD may comprise an anode contact located adjacent the metal layer.

### GENERAL CONSIDERATIONS

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, the various example materials identified herein may, in some aspects, be replaced or supplemented with substantially any other suitable material. For example, according to some aspects of the example SBD, the semiconductor material may include silicon carbide, gallium nitride, zinc oxide, or other suitable material.

It will be appreciated that the sides of the illustrated volume of semiconductor material are defined herein merely as an example, and may in various examples represent only a portion of semiconductor material relative to the illustrated device. In practice, the volume of semiconductor material may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be similarly or alternatively constructed to the illustrated SBD 100 or may be entirely different devices providing different operations or functions than the illustrated device 100. In other words, in practice, the illustrated device 100 may be just one of numerous devices spaced laterally and transversely within a single, integrally formed component, such as a wafer or integrated circuit (not shown).

Additionally, in general, unless otherwise specified or unless one with ordinary skill in the art would understand otherwise, doping concentrations (generally measured in parts-per-cubic-centimeter) for contact implants may be approximately between 5×10\hat{ }18 and 1×10\hat{ }22; doping concentrations for channel and threshold forming implants (e.g., P-wells) may be approximately between 5×10\hat{ }15 and 5×10\hat{ }17; doping concentrations for shielding implants may be approximately between 1×10\hat{ }17 and 1×10\hat{ }19; and doping concentrations for conductivity improvement implants may be approximately between 1×10\hat{ }16 and 1×10\hat{ }17.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

In this description, references to “one embodiment,” “an embodiment,” “embodiments,” “an example,” “one example,” or “examples” mean that the feature or features being referred to are included in at least one embodiment or example of the technology. Separate references to “one embodiment,” “an embodiment,” “embodiments,” “an example,” “one example,” or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated or as may be readily apparent to those skilled in the art.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. §112(f) unless traditional means-plus-function language is expressly recited, such as “means for” or “step for” language being explicitly recited in the claim(s).

What is claimed is:

1. A Schottky barrier diode (SBD), comprising:
a volume of semiconductor material presenting opposite first and second ends;
a metal layer contacting the first end to define a Schottky contact; and
a plurality of doped material pockets dispersed in the volume of semiconductor material adjacent the first end,
each of the doped material pockets extending from the first end to define a cross-sectional shape relative to the direction of extension,
the cross-sectional shape of each of the doped material pockets presenting a body and a projection extending laterally from the body.

2. The SBD of claim 1, the doped material pockets being uniformly arranged in a repeating pattern.

3. The SBD of claim 2,
the Schottky contact being located between the doped material pockets.

4. The SBD of claim 3, the metal layer including a metal being selected from the group consisting of: titanium, molybdenum, platinum, chromium, tungsten, aluminum, and combinations thereof.

5. The SBD of claim 2, the repeating pattern being configured so that the Schottky contact is uninterrupted.

6. The SBD of claim 1, wherein the projection and body cooperatively define a recess, with adjacent doped material pockets presenting an opposed projection and recess pair to thereby minimize a gap between the adjacent ones of the doped material pockets.

7. The SBD of claim 6, wherein the projection of the pair extends into the recess of the pair.

8. The SBD of claim 7, the body including opposite sides, at least some of the doped material pockets including a pair of the projections extending from one of the sides, with the recess being defined between the pair of projections.

9. The SBD of claim 6, the projection and recess of the pair presenting complementary shapes.

10. The SBD of claim 9, each of the projections being orthogonal, and each of the recesses defining an interior right angle.

11. The SBD of claim 10, the cross-sectional shape of each of the doped material pockets being a cruciform.

12. The SBD of claim 6, the doped material pockets being uniformly arranged in a repeating pattern.

13. The SBD of claim 12, the repeating pattern being configured so that the Schottky contact is uninterrupted.

14. The SBD of claim 13, the body including opposite sides, at least some of the doped material pockets including a pair of the projections extending from one of the sides, with the recess being defined between the pair of projections.

15. The SBD of claim 14, each of the projections being orthogonal, and each of the recesses defining an interior right angle.

16. The SBD of claim 1, comprising:
a cathode substrate located at the second end.

17. The SBD of claim 16,
the cathode substrate including an N+ material,
the volume of semiconductor material including an N-type epitaxial material,
the doped material pockets including a P+ material.

18. The SBD of claim 16, comprising:
a cathode contact located adjacent the cathode substrate.

19. The SBD of claim 18, comprising:
an anode contact located adjacent the metal layer.

20. The SBD of claim 1, the cross-sectional shape of each of the doped material pockets being a cruciform.
